(19) United States
(12) Patent Application Publication
(10) Pub. No.: US 2025/0230036 A1
(43) Pub. Date: Jul. 17, 2025

(54) PACKAGE STRUCTURE AND METHOD OF FORMING THE SAME

(71) Applicant: TAIWAN SEMICONDUCTOR MANUFACTURING COMPANY LTD., HSINCHU (TW)

(72) Inventors: WEN-TUAN LO, HSINCHU CITY (TW); SHANG-YING TSAI, TAOYUAN CITY (TW); KUEI-SUNG CHANG, KAOHSIUNG CITY (TW)

(21) Appl. No.: 18/413,073

(22) Filed: Jan. 16, 2024

(51) Int. Cl. B81B 7/00; B81B 3/00; B81C 1/00

(52) U.S. Cl. CPC B81B 7/0064; B81B 3/0021; B81C 1/00333; B81C 2203/0145

(57) ABSTRACT

The present disclosure provides a semiconductor package structure and a manufacturing method thereof. The semiconductor package structure includes: a substrate; a chip disposed on the substrate; and a molding material disposed on the substrate and surrounding the chip. The chip includes: a cavity; and a movable element disposed within and movable within the cavity and configured to sense or output a force.

### BACKGROUND

Semiconductor devices are typically packaged using a molding material, and then may be installed on a substrate that includes electrical circuitry, such as a printed circuit board (PCB). As semiconductor technology advances, package structures become shrinking. After the semiconductor device is packaged, some parameters related to the semiconductor device inside the package structure are difficult to control.

Therefore, there is a continuous need to modify the package structure and the manufacturing method for controlling parameters inside the package structure.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a schematic cross-sectional view showing a semiconductor package structure, in accordance with some embodiments of the present disclosure.

FIG. 2 is a schematic cross-sectional view of a chip of the semiconductor package structure in FIG. 1, in accordance with some embodiments of the present disclosure.

FIG. 3 is a schematic cross-sectional view showing a semiconductor package structure, in accordance with other embodiments of the present disclosure.

FIG. 4 is a schematic cross-sectional view showing a semiconductor package structure, in accordance with other embodiments of the present disclosure.

FIG. 5 is a schematic cross-sectional view showing a semiconductor package structure, in accordance with other embodiments of the present disclosure.

FIG. 6 is a schematic cross-sectional view showing a semiconductor package structure, in accordance with other embodiments of the present disclosure.

FIG. 7 is a schematic cross-sectional view showing a semiconductor package structure, in accordance with other embodiments of the present disclosure.

FIG. 8 is a schematic cross-sectional view showing a semiconductor package structure, in accordance with other embodiments of the present disclosure.

FIG. 9 is a flow diagram showing a method of fabricating a package structure, in accordance with some embodiments of the present disclosure.

FIGS. 10 to 19 are schematic cross-sectional or top views illustrating sequential operations of the method in FIG. 9, in accordance with some embodiments of the present disclosure.

FIG. 20 is a flow diagram showing a method of fabricating another package structure, in accordance with some embodiments of the present disclosure.

FIGS. 21 to 27 are schematic cross-sectional views illustrating sequential operations of the method in FIG. 20, in accordance with some embodiments of the present disclosure.

FIG. 28 is a flow diagram showing a method of fabricating another package structure, in accordance with some embodiments of the present disclosure.

FIGS. 29 to 37 are schematic cross-sectional views illustrating sequential operations of the method in FIG. 28, in accordance with some embodiments of the present disclosure.

### DETAILED DESCRIPTION OF THE DISCLOSURE

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In some embodiments, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass orientations of the device in use or operation in some embodiments different from the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” or “about” generally mean within a value or range which can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

A complementary metal-oxide semiconductor (CMOS) process is one of many commercial semiconductor processes that are used to produce integrated circuits (ICs). The use of the CMOS process to develop microelectromechanical system (MEMS) devices is called CMOS-MEMS technology. Many sensors and devices are fabricated and commercialized using this technology; examples include accelerometers, pressure sensors, thermal sensors, image sensors, microphones, inkjet heads, and digital micro-mirror devices. Micro devices developed by the technology have potential for commercialization and mass production.

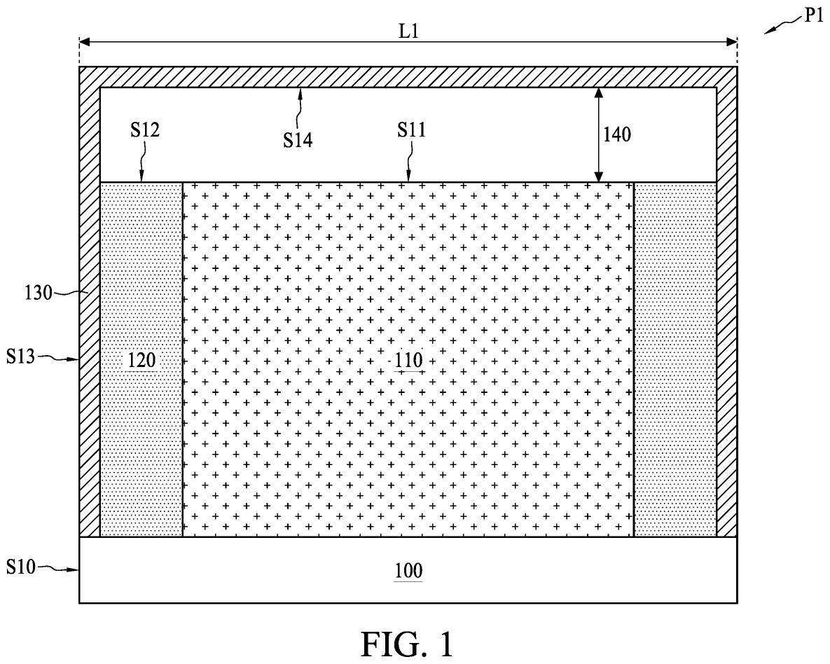

FIG. 1 is a schematic cross-sectional view showing a semiconductor package structure P1 according to some embodiments of the present disclosure. The semiconductor package structure P1 includes a substrate 100 and a chip 110 disposed on the substrate 100. The substrate 100 may be a PCB with electrical circuitry comprised of metal traces or metal pads. The chip 110 is electrically connected to the electrical circuitry of the substrate 100. A molding material 120 is disposed on the substrate 100 and surrounds the chip 110. A housing 130 is disposed on the substrate 100 and covers the chip 110 and the molding material 120. In some embodiments, a length or width L1 of the housing 130 is between about 0.1 millimeter (mm) and about 10 mm. An exterior surface S13 of the housing 130 may be coplanar with an edge S10 of the substrate 100. The exterior surface S13 of the housing 130 may be coupled to and continuous with the edge S10 of the substrate 100.

In some embodiments, the molding material 120 includes, but is not limited to, epoxy resin, polymer, silica, a combination thereof or other suitable materials. The molding material 120 may partially fill space defined by the substrate 100, the chip 110 and the housing 130. In some embodiments, the molding material 120 does not cover the chip 110, as shown in FIG. 1. A top surface S12 of the molding material 120 may be substantially coplanar with a top surface S11 of the chip 110 exposed through the molding material 120. In such embodiments, an interior surface S14 of the housing 130 faces the top surface S11 of the chip 110 and the top surface S12 of the molding material 120. The interior surface S14 of the housing 130 may be spaced apart from the chip 110 and the molding material 120 by a gap 140.

The housing 130 may be used as a dust cover that prevents dust or particles from settling on the chip 110 and the substrate 100. In some embodiments, the housing 130 comprises a metallic material. The metallic housing 130 may function as a shielding enclosure to reduce disturbance of electromagnetic radiation from other electronic devices. In some other embodiments, when the chip 110 is not at risk of the effects of electromagnetic radiation, the housing 130 is made of an insulative material.

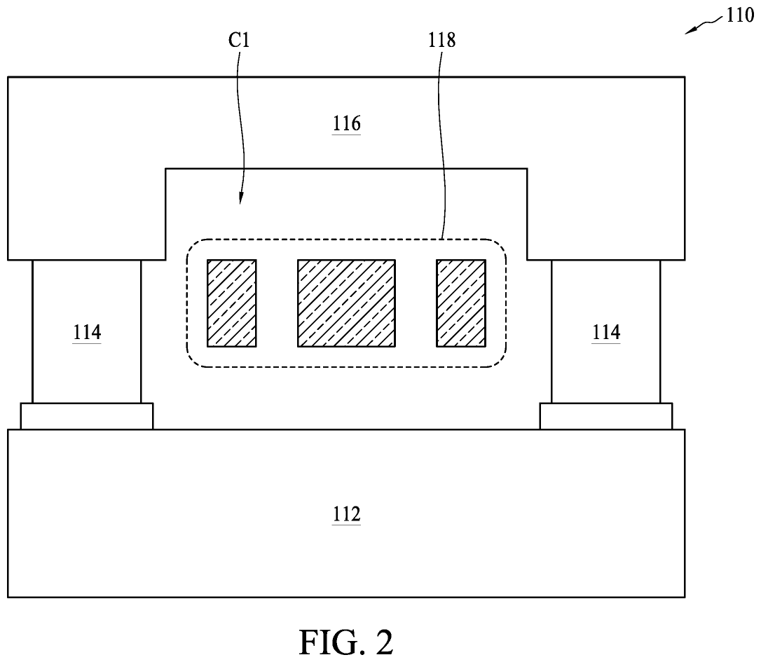

FIG. 2 is a schematic cross-sectional view of the chip 110 in FIG. 1. In some embodiments, the chip 110 is an MEMS integrated chip (e.g., a CMOS-MEMS integrated chip). The chip 110 may include a device substrate 112, multiple support members 114 disposed on the device substrate 112 and a capping member 116 disposed on the support members 114. The device substrate 112 and the capping member 116 are bonded by the support members 114. Electrical circuitry disposed in the chip 110 is not shown for brevity. In some embodiments, the device substrate 112 includes a die of an application-specific integrated circuit (ASIC) wafer. In some embodiments, one or more movable elements 118 are arranged between the device substrate 112 and the capping member 116. In the example shown in FIG. 2, one movable element 118 is shown; however, in other examples, the number of the movable elements 118 may be more than one (e.g. two, three, four, five, six, or more).

In some embodiments, the movable element 118 is used to sense a signal, sense a force, output a signal or output a force. In order to allow for movement of the movable element 118, the chip 110 have one or more cavities C1 disposed therein for free movement of the movable element 118. The cavity C1 may be disposed between the device substrate 112 and the capping member 116 and between two neighboring support members 114. The cavity C1 is aligned with the movable element 118, as shown in FIG. 2. As such, the movable element 118 is movable within the cavity C1. The configuration of the movable element 118 shown in FIG. 2 is only schematic. For different applications, the movable element 118 may have different configurations or parts. For example, when the chip 110 is a capacitive micromachined ultrasonic transducer (CMUT) or a piezoelectric micromachined ultrasonic transducer (PMUT), the movable element 118 may include a vibrating membrane and multiple electrodes. In some embodiments, the chip 110 functions as a motion sensor, a motion stabilizer, a gyroscope, an accelerometer, a G-sensor, a pressure gauge, a thermal sensor, an image sensor, an inkjet head, a capacitive barometer, a microfluidic chip, a biological gene chip, a microphone, a speaker or the like.

Referring to FIGS. 1 and 2, the movable element 118 between the device substrate 112 and the capping member 116 and within the cavity C1 is sensitive to vibrations. In some cases, a large vibration may cause the movable element 118 to generate incorrect signals. The molding material 120 may function as a shock absorbing material for reducing shock that the chip 110 suffers from. When the semiconductor package structure P1 is struck by an external force, the molding material 120 can protect the chip 110 by absorbing the shock caused by the external force.

On the other hand, when a reliability test (e.g., a drop test) is conducted on the semiconductor package structure P1, an amount of the molding material 120 related to a shock absorption performance of the molding material 120 surrounding the chip 110 is evaluated. The shock absorption performance may refer to an ability of the molding material 120 to absorb an energy of impact. The amount of the molding material 120 can be adjusted in order for the semiconductor package structure P1 to pass the reliability test. Furthermore, different MEMS structures or MEMS products also use different amounts of the molding material 120 due to their different shock resistances.

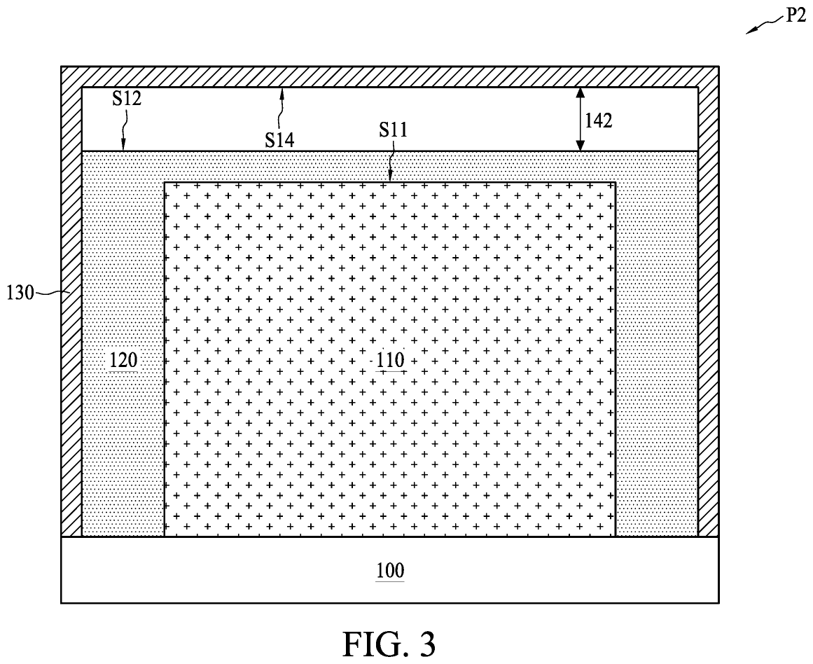

FIG. 3 is a schematic cross-sectional view showing a semiconductor package structure P2 according to other embodiments of the present disclosure. The semiconductor package structure P2 is similar to the semiconductor package structure P1 in FIG. 1, except that, in the semiconductor package structure P2, the molding material 120 covers the chip 110. In such embodiments, the top surface S12 of the molding material 120 is higher than the top surface S11 of the chip 110. The top surface S12 of the molding material 120 is between the top surface S11 of the chip 110 and the interior surface S14 of the housing 130 facing the top surface S11 of the chip 110. The interior surface S14 of the housing 130 may be spaced apart from the molding material 120 by a gap 142. A volume of the gap 142 is less than a volume of the gap 140 of the semiconductor package structure P1.

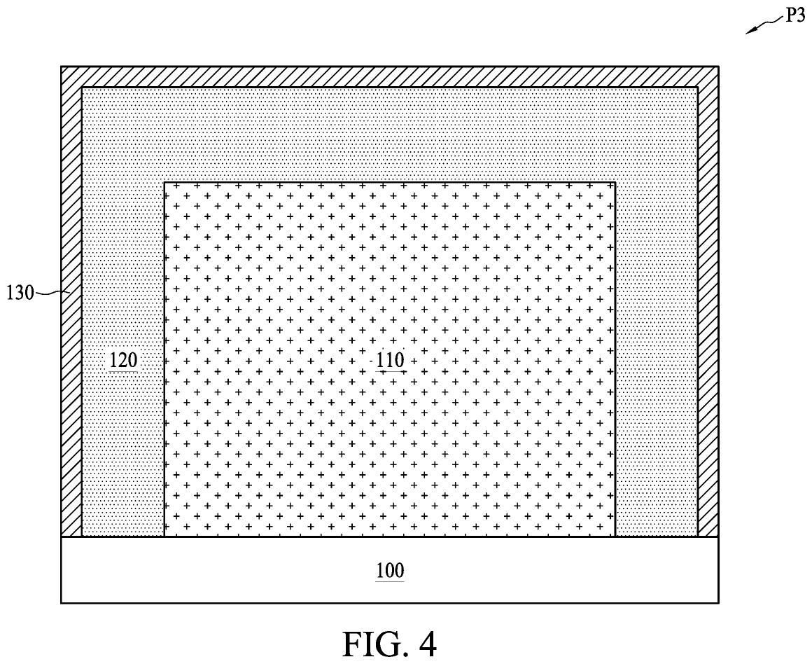

FIG. 4 is a schematic cross-sectional view showing a semiconductor package structure P3 according to other embodiments of the present disclosure. The semiconductor package structure P3 is similar to the semiconductor package structure P2 in FIG. 3, except that, in the semiconductor package structure P3, the molding material 120 completely fills the space defined by the substrate 100, the chip 110 and the housing 130. In such embodiments, the molding material 120 contacts all interior surfaces of the housing 130, and there is no gap within the housing 130.

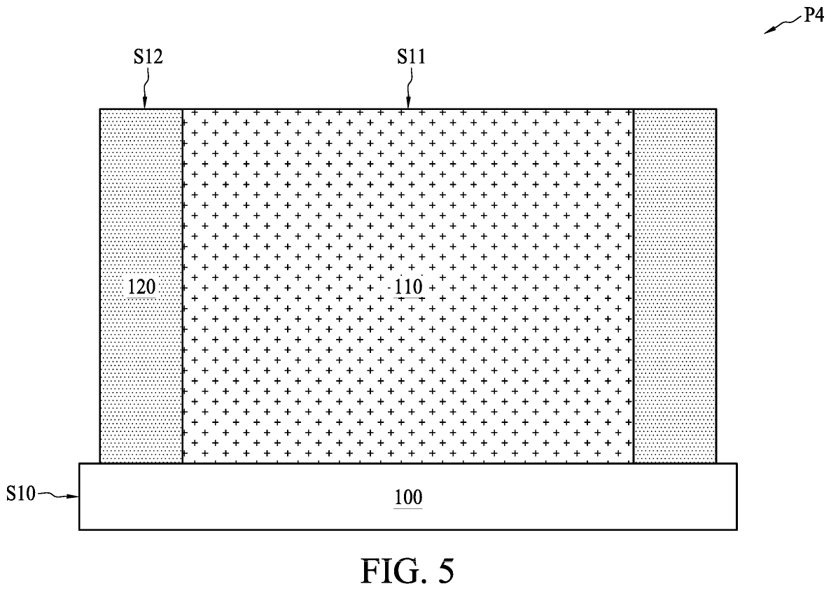

FIG. 5 is a schematic cross-sectional view showing a semiconductor package structure P4 according to other embodiments of the present disclosure. The semiconductor package structure P4 is similar to the semiconductor package structure P1 in FIG. 1, except that the semiconductor package structure P4 does not include a housing. In some embodiments, if the chip 110 is resistant to or not sensitive to the effect of electromagnetic radiation, the semiconductor package structure P4 does require a housing (e.g., a metallic housing). In some embodiments, the edge S10 of the substrate 100 protrudes from the molding material 120.

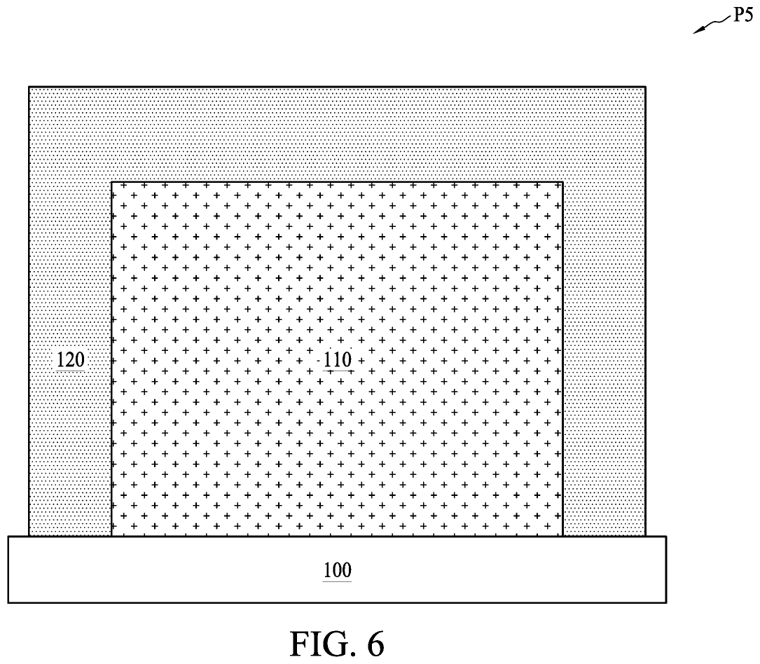

FIG. 6 is a schematic cross-sectional view showing a semiconductor package structure P5 according to other embodiments of the present disclosure. The semiconductor package structure P5 is similar to the semiconductor package structure P2 in FIG. 3 or the semiconductor package structure P3 in FIG. 4, except that the semiconductor package structure P5 does not include a housing (e.g., a metallic housing). Without a housing, the chip 110 enclosed solely by the molding material 120 can be protected from contamination by dust, moisture or particles.

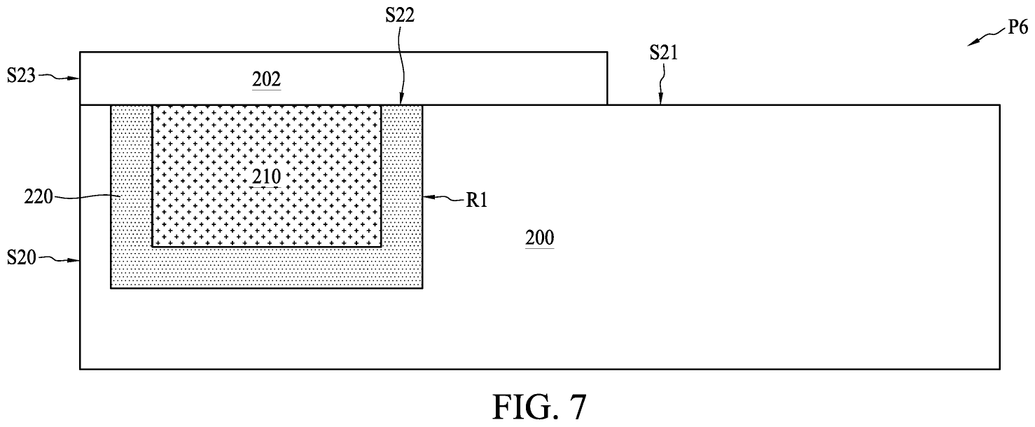

FIG. 7 is a schematic cross-sectional view showing a semiconductor package structure P6 according to other embodiments of the present disclosure. The semiconductor package structure P6 includes a first substrate 200, a second substrate 202 mounted onto the first substrate 200, and a chip 210 disposed on the first substrate 200. The first substrate 200 and the second substrate 202 are respectively PCB, device, or a part of PCB, a part of device, or the like. In some embodiments, the first substrate 200 is a mobile phone circuit board. The chip 210 may be similar to the chip 110 in FIGS. 1 to 6. That is, the chip 210 may be an MEMS integrated chip that includes one or more movable elements disposed therein. The chip 210 may be a CMUT, a PMUT, a motion sensor, a motion stabilizer, a gyroscope, an accelerometer, a G-sensor, a pressure gauge, a thermal sensor, an image sensor, an inkjet head, a capacitive barometer, a microfluidic chip, a biological gene chip, a microphone, a speaker or the like.

In some embodiments, the first substrate 200 includes a recess R1, and the chip 210 is disposed within the recess R1. The chip 210 may be electrically connected to electrical circuitry of the second substrate 202, and further connected to electrical circuitry of the first substrate 200. A molding material 220 is disposed within the recess R1 of the first substrate 200 and surrounds the chip 210. In some embodiments, the molding material 220 and the chip 210 completely fill the recess R1 of the first substrate 200. A sidewall of the recess R1 may be entirely covered by the molding material 220. The second substrate 202 may cover and directly contact the chip 210, the molding material 220 and a portion of the first substrate 200. A top surface S22 of the molding material 220 may be substantially coplanar with a top surface S21 of the first substrate 200. A sidewall S23 of the second substrate 202 may be coplanar with a sidewall S20 of the first substrate 200.

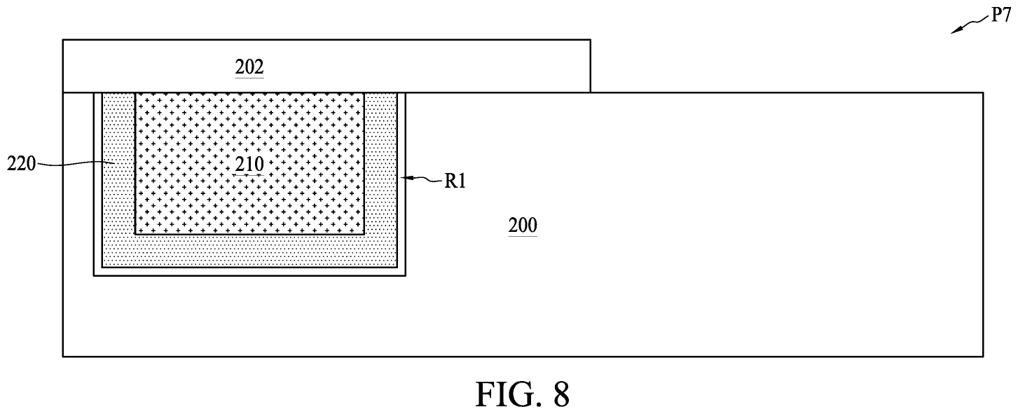

FIG. 8 is a schematic cross-sectional view showing a semiconductor package structure P7 according to other embodiments of the present disclosure. The semiconductor package structure P7 is similar to the semiconductor package structure P6 in FIG. 7, except that, in the semiconductor package structure P7, the molding material 220 and the chip 210 partially fill the recess R1 of the first substrate 200. In such embodiments, the sidewall of the recess R1 does not contact the molding material 220 that encases the chip 210. The molding material 220 is disposed within the first substrate 220 while spaced apart from the first substrate 220.

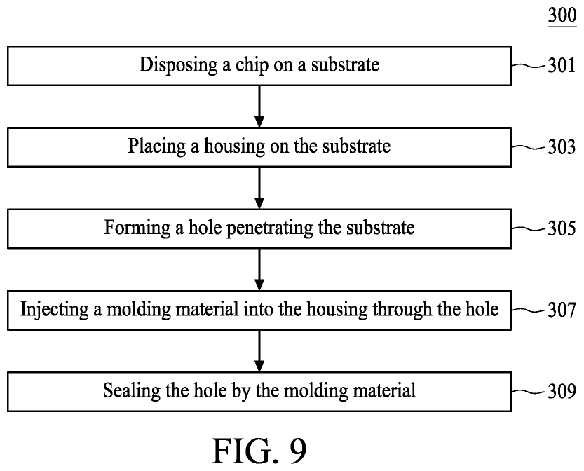

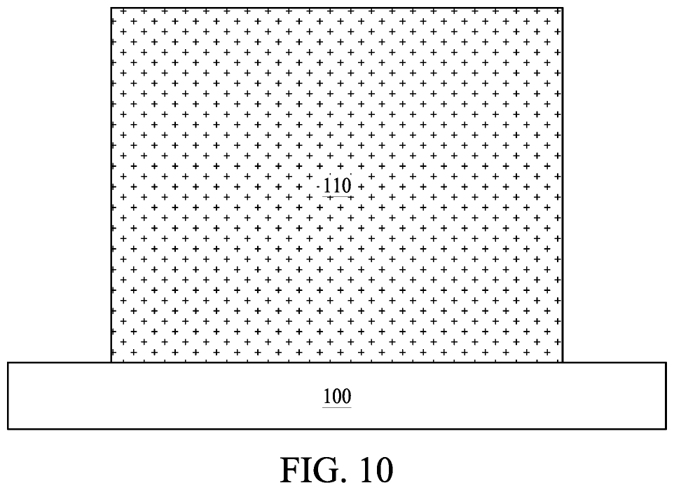

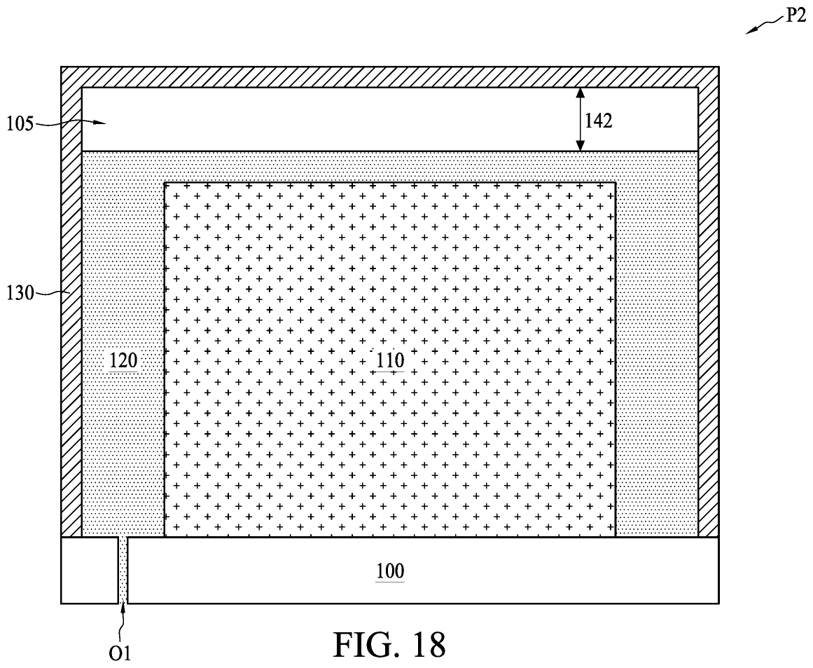

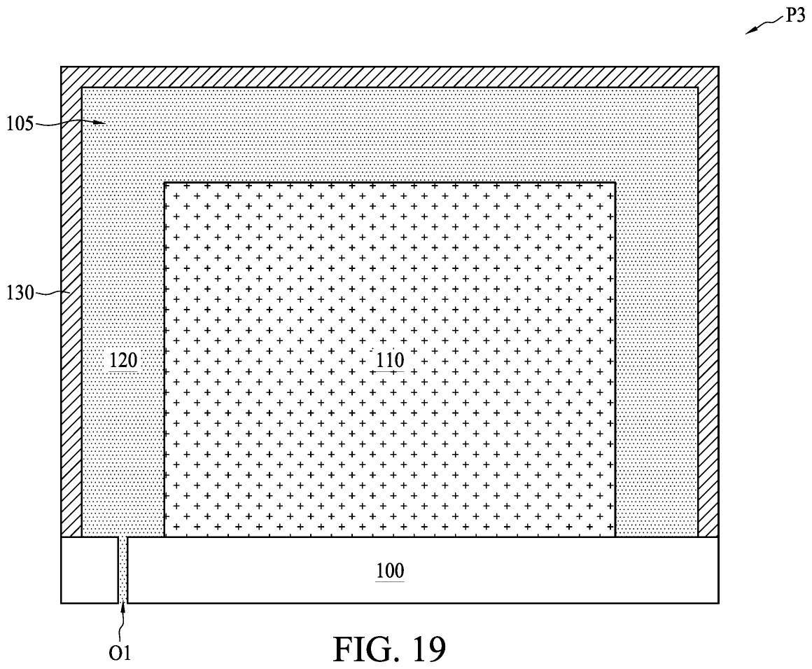

FIG. 9 is a flow diagram showing a method 300 of fabricating a package structure. FIGS. 10 to 19 are schematic cross-sectional or top views illustrating sequential operations of the method 300 in FIG. 9. In following paragraphs, descriptions of elements with same labels provided with respect to FIGS. 1 to 8 are generally applicable herein and, for brevity, are not repeated here.

In operation 301, a chip 110 is disposed on a substrate 100, as shown in FIG. 10. The chip 110 is electrically connected to electrical circuitry of the substrate 100.

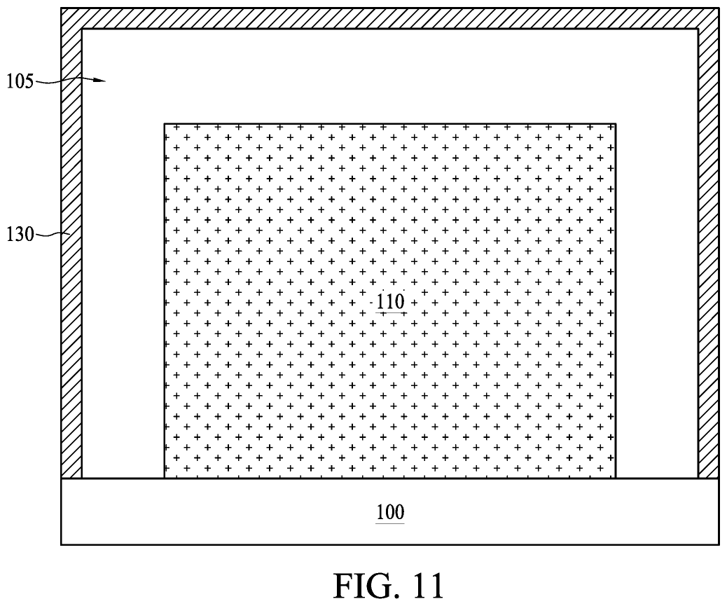

In operation 303, a housing 130 is placed on the substrate 100, as shown in FIG. 11. The housing 130 covers the chip 110 and can be used as a mold for subsequent operations. The housing 130 can also prevent dust, moisture or particles from contaminating the chip 110 and the substrate 100. In some embodiments, the housing 130 is a metallic shielding enclosure for reducing an effect of electromagnetic radiation on the chip 110. In some other embodiments, the housing 130 is an insulative enclosure if the chip 110 is not sensitive to the effect of electromagnetic radiation. A space 105 may be defined by the substrate 100, the chip 110 and the housing 130.

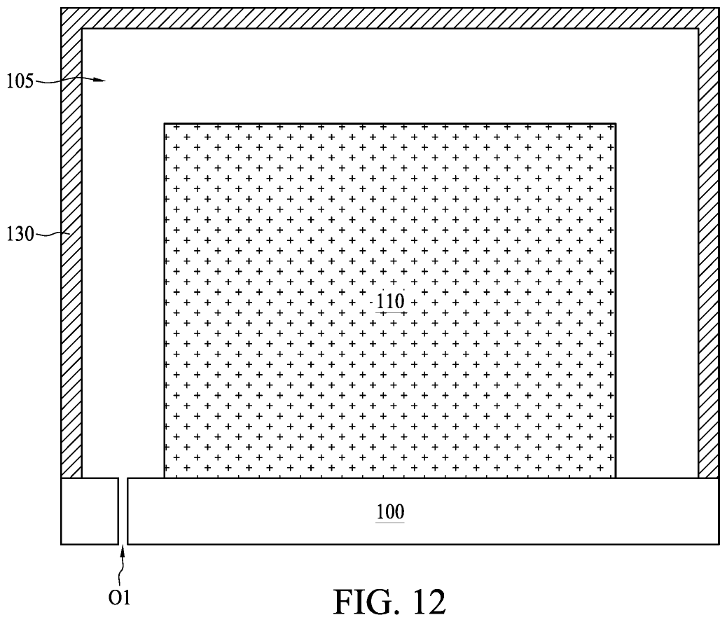

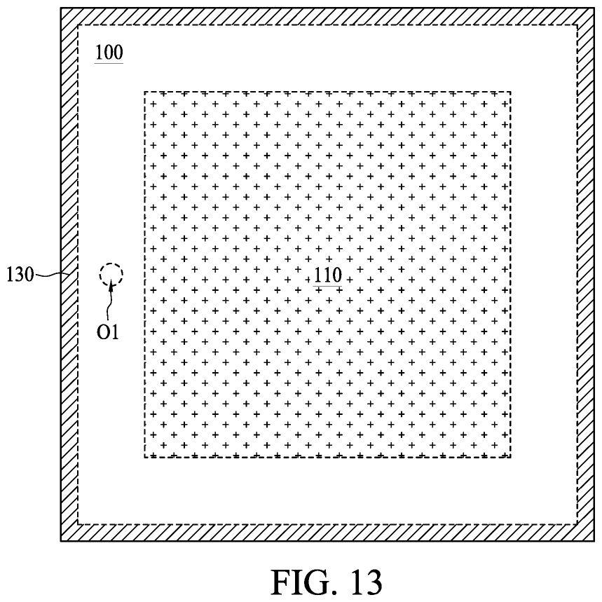

In operation 305, a hole O1 is formed penetrating the substrate 100, as shown in FIGS. 12 and 13. FIG. 12 is a schematic cross-sectional view illustrating operation 305, and FIG. 13 is a schematic top view illustrating operation 305. In some embodiments, the hole O1 is formed by a laser drilling process. This hole O1 is formed within a coverage area of the housing 130 and is separated from the chip 110.

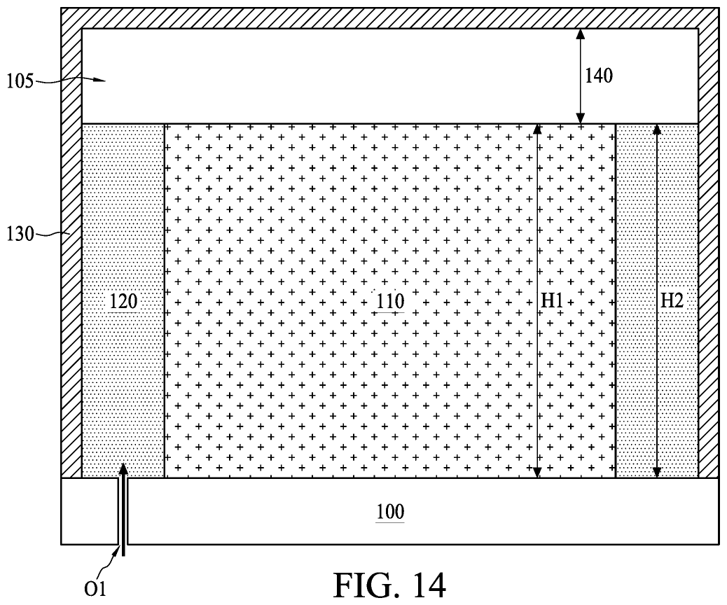

In operation 307, a molding material 120 is injected into the housing 130 through the hole O1, as shown in FIGS. 14 to 16. The molding material 120 includes, but is not limited to, epoxy resins, epoxy polymers, a combination thereof, or other suitable materials. In some embodiments, the molding material 120 is in a form of gel or liquid solution. In such embodiments, the molding material 120 can flow into the space 105 through the hole O1. As more molding material 120 is injected into the space 105, the chip 110 is gradually surrounded by the molding material 120.

In some embodiments, the injection of the molding material 120 is stopped when a height H2 of the molding material 120 is substantially equal to a height H1 of the chip 110, as shown in FIG. 14. In such embodiments, the molding material 120 does not cover the chip 110 and partially fills the space 105. A gap 140 is formed over the chip 110 and the molding material 120 within the housing 130.

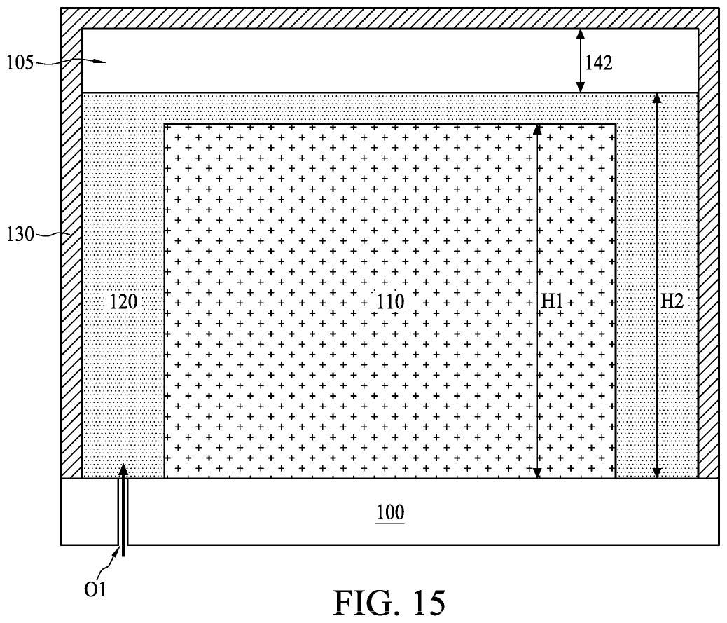

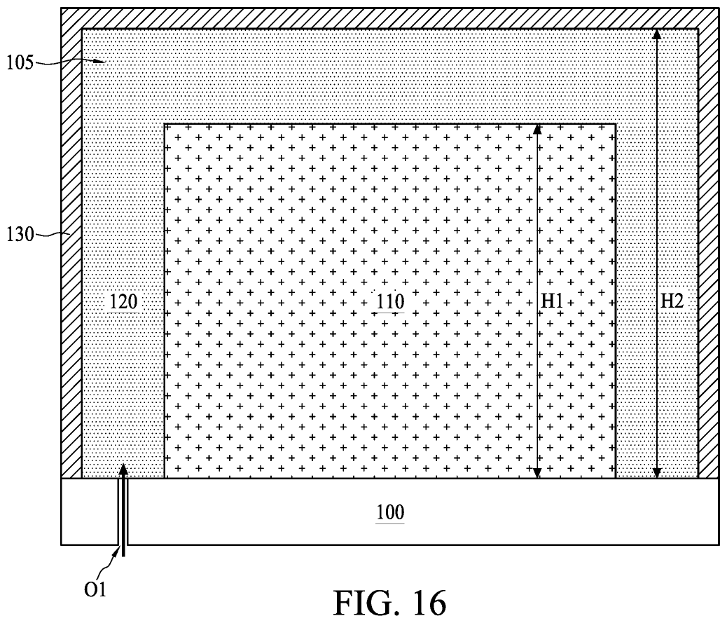

In some other embodiments, the injection of the molding material 120 is stopped when the height H2 of the molding material 120 is greater than the height H1 of the chip 110, as shown in FIGS. 15 and 16. In such embodiments, the chip 110 is entirely covered by the molding material 120. Referring to FIG. 15, a gap 142 is formed over the molding material 120 within the housing 130 when the space 105 is not completely filled by the molding material 120. Referring to FIG. 16, the space 105 is completely filled by the molding material 120.

After the molding material 120 is injected, the molding material 120 gradually hardens as its solvent evaporates. The hardening of the molding material 120 may take place at room temperature or at higher temperatures. In some embodiments, a curing operation is performed on the molding material 120. The curing operation may include heating or light illumination of the molding material 120 to cause the molding material 120, which is originally in a form of gel or liquid solution, to be sufficiently solidified.

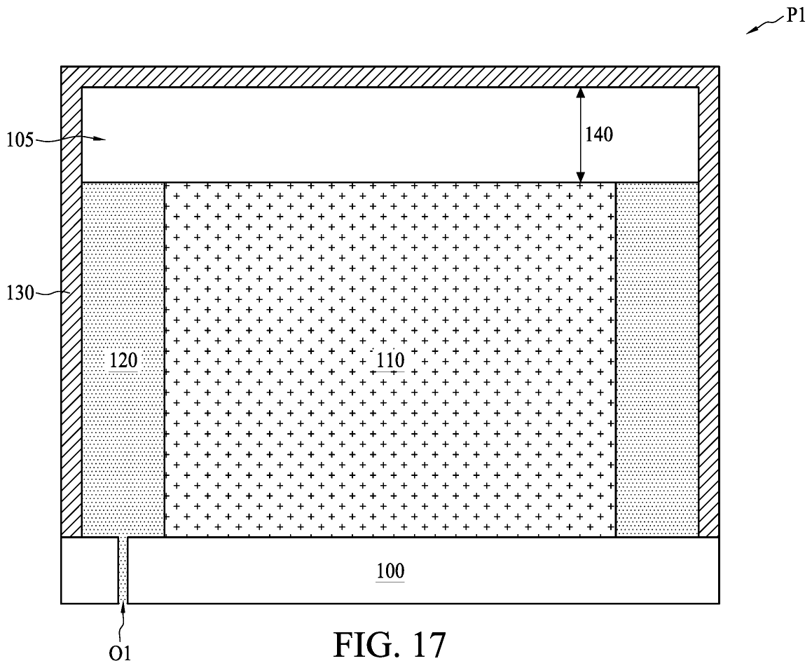

In operation 309, the hole O1 is sealed by the molding material 120, as shown in FIGS. 17 to 19. FIGS. 17 to 19 respectively follow FIGS. 14 to 16. After the molding material 120 in the space 105 becomes solidified, more molding material 120 may be injected to fill the hole O1. At this stage, the semiconductor package structures P1, P2 and P3 respectively shown in FIGS. 1, 3 and 4 are formed. In some embodiments, the housing 130 is removed after the semiconductor package structure P1, P2 or P3 is formed, and thus the semiconductor package structure P4 in FIG. 5 or the semiconductor package structure P5 in FIG. 6 is formed. When the housing 130 is removed, an edge S10 of the substrate 100 protrudes from the molding material 120.

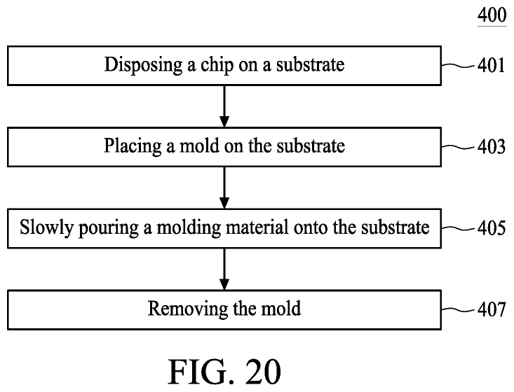

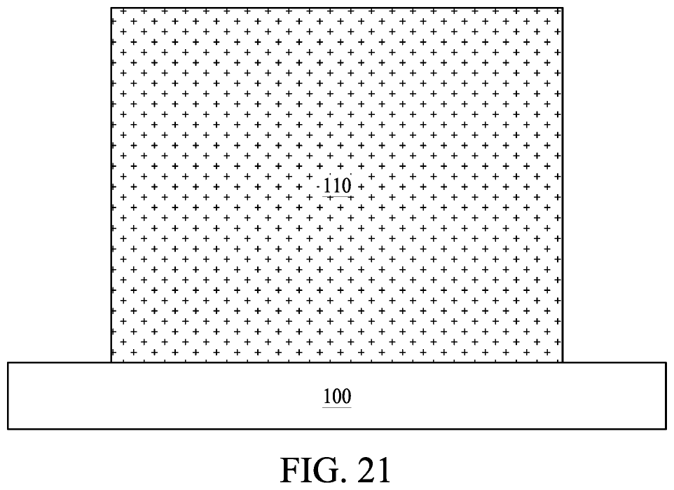

FIG. 20 is a flow diagram showing a method 400 of fabricating a package structure. FIGS. 21 to 27 are schematic cross-sectional views illustrating sequential operations of the method 400 in FIG. 20.

In operation 401, a chip 110 is disposed on a substrate 100, as shown in FIG. 21. The chip 110 is electrically connected to electrical circuitry of the substrate 100.

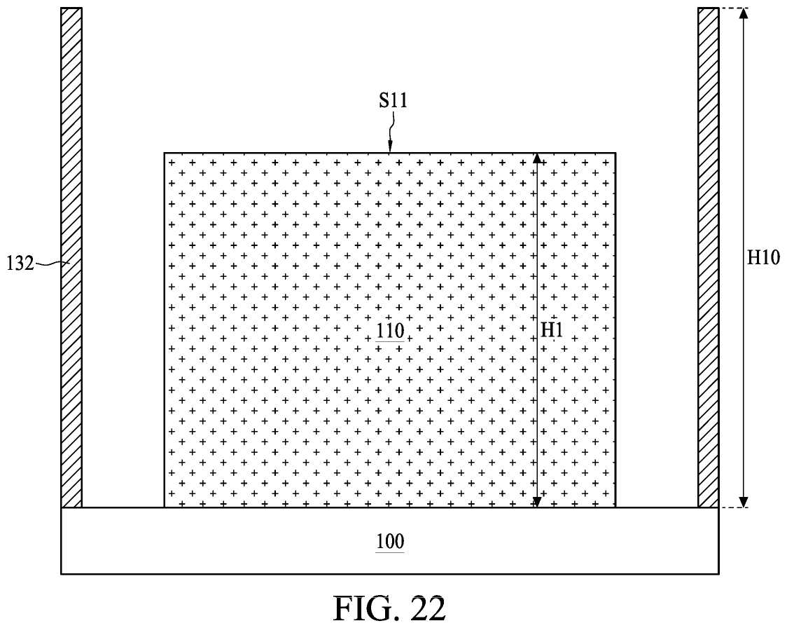

In operation 403, a mold 132 is placed on the substrate 100 and surrounds the chip 110, as shown in FIG. 22. The mold 132 may comprise metals, silicone, foam, wood, plastics or other suitable materials. A height H10 of the mold 132 may be greater than a height H1 of the chip 110.

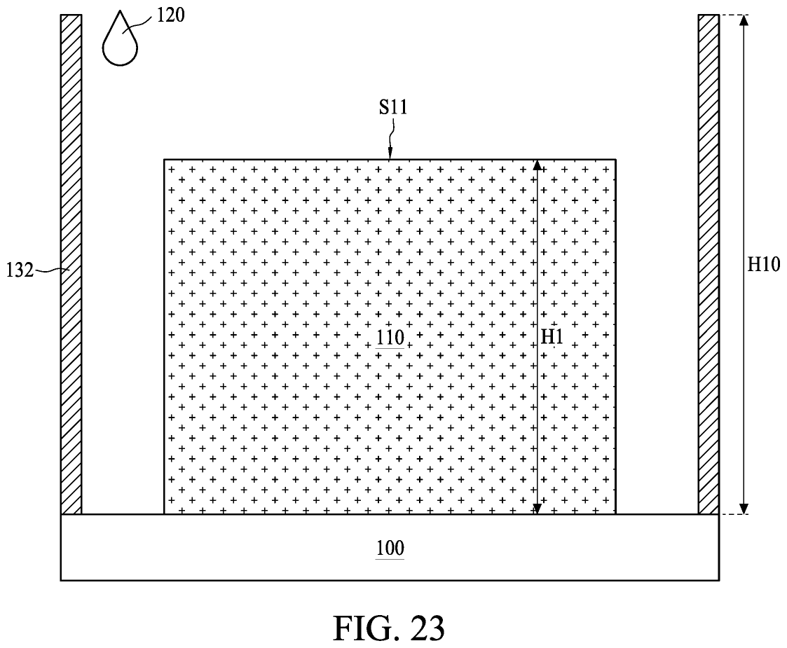

In operation 405, a molding material 120 is slowly poured onto the substrate 100, as shown in FIGS. 23 to 25. As more of the molding material 120 flows into a space defined by the substrate 100, the chip 110 and the mold 132, side walls of the chip 110 are gradually surrounded by the molding material 120.

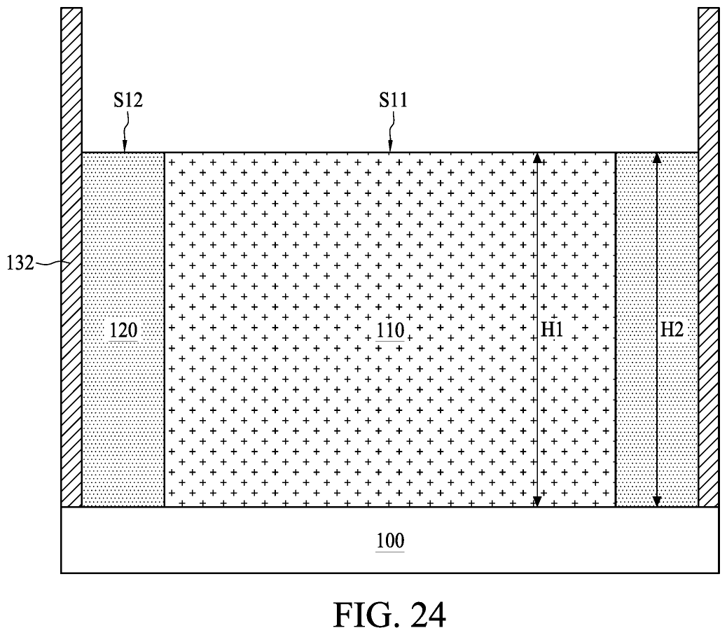

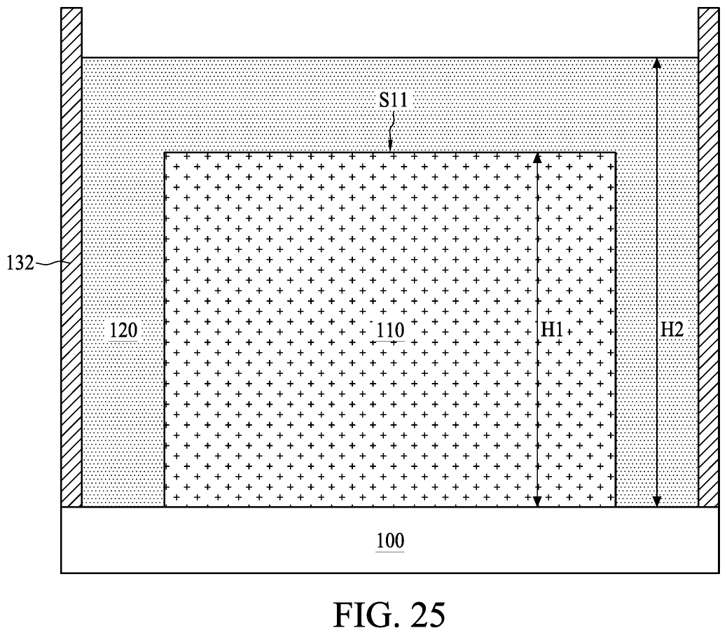

In some embodiments, the pouring of the molding material 120 is stopped when a height H2 of the molding material 120 is substantially equal to the height H1 of the chip 110, as shown in FIG. 24. That is, a top surface S12 of the molding material 120 is substantially coplanar with a top surface S11 of the chip 110. In such embodiments, the molding material 120 does not cover the chip 110. In some other embodiments, the pouring of the molding material 120 is stopped when the height H2 of the molding material 120 is greater than the height H1 of the chip 110, as shown in FIG. 25. In such embodiments, the chip 110 is entirely covered by the molding material 120.

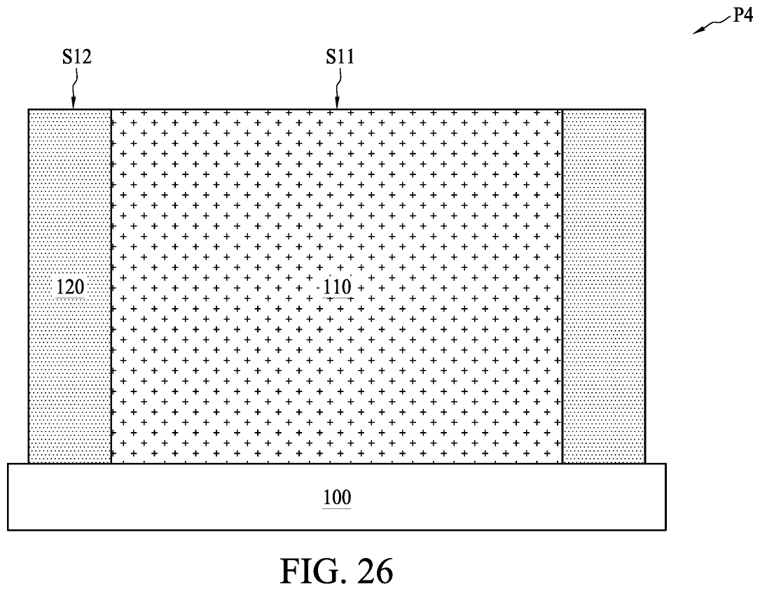

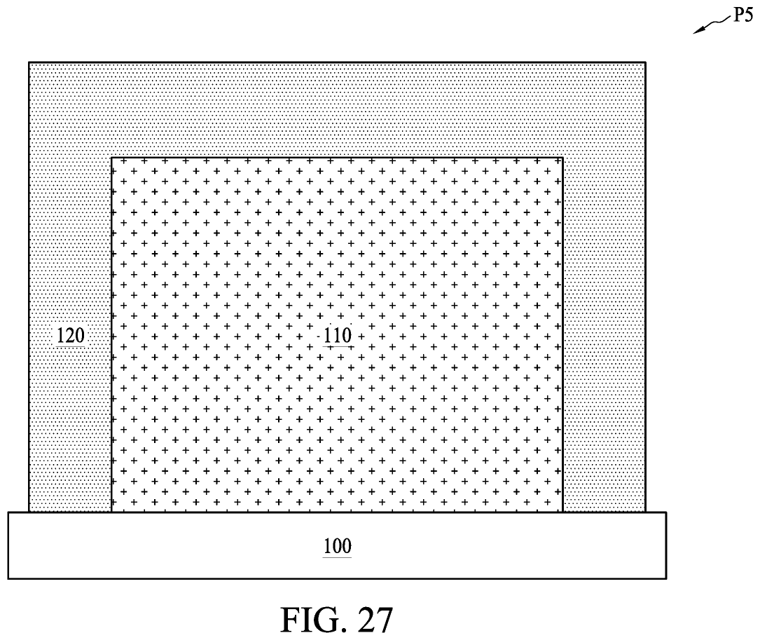

In operation 407, the mold 132 is removed, as shown in FIGS. 26 and 27. FIGS. 26 and 27 are respectively continued from FIGS. 24 and 25. A curing operation may be performed on the molding material 120 to accelerate its solidification. When the molding material 120 becomes sufficiently solidified, the mold 132 can be removed. At this stage, the semiconductor package structure P4 in FIG. 5 or the semiconductor package structure P5 in FIG. 6 is formed. The semiconductor package structures P4 and P5 may be formed using the method 300 or the method 400.

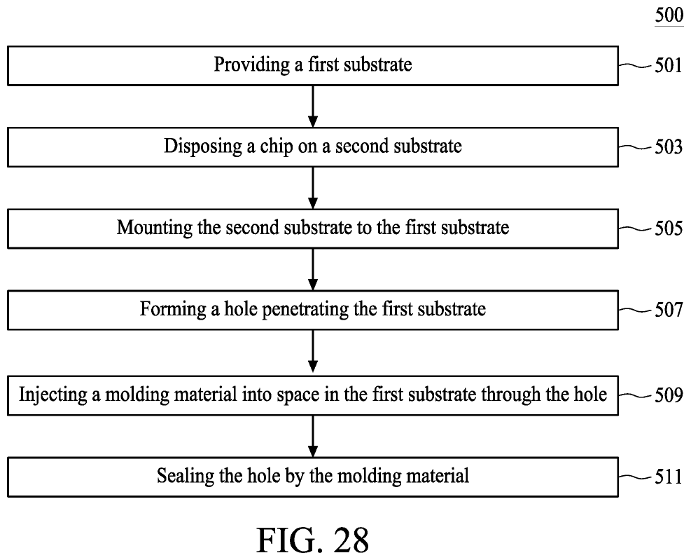

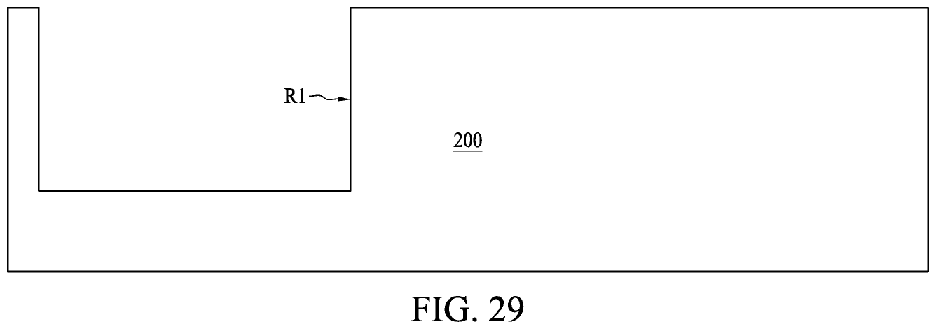

FIG. 28 is a flow diagram showing a method 500 of fabricating a package structure. FIGS. 29 to 37 are schematic cross-sectional views illustrating sequential operations of the method 500 in FIG. 28.

In operation 501, a first substrate 200 is provided, as shown in FIG. 29. The first substrate 200 may be a mobile phone circuit board. In some embodiments, the first substrate 200 includes a recess R1.

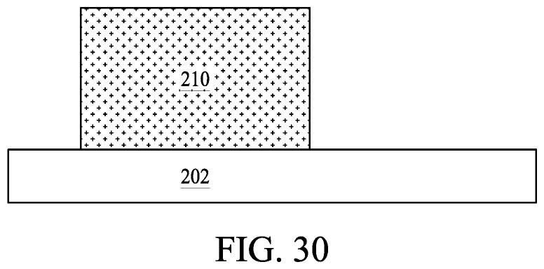

In operation 503, a chip 210 is disposed on a second substrate 202, as shown in FIG. 30. The second substrate 202 may be a PCB. The chip 210 and the second substrate 202 may be similar to the chip 110 and the substrate 100 in FIG. 10, respectively. The chip 210 is electrically connected to electrical circuitry of the second substrate 202. In some embodiments, a volume of the recess R1 is greater than a volume of the chip 210.

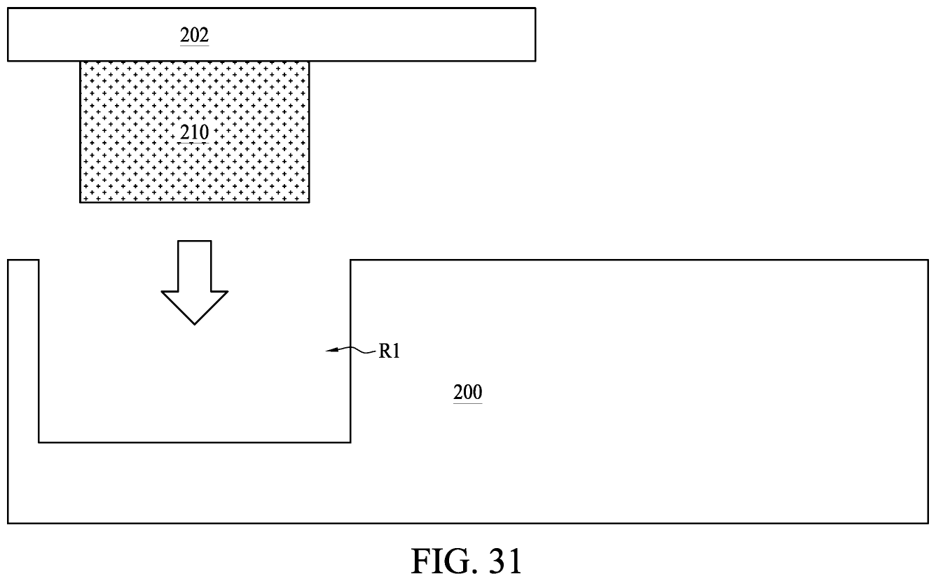

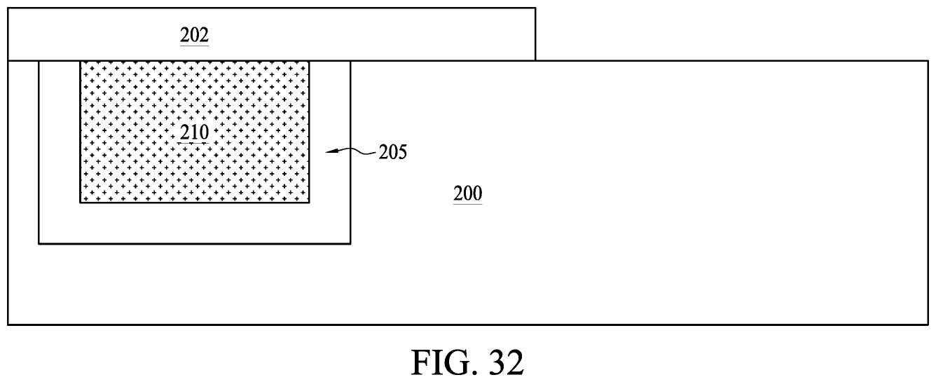

In operation 505, the second substrate 202 is mounted onto the first substrate 200, as shown in FIGS. 31 and 32. Referring to FIG. 31, the chip 210 disposed on the second substrate 202 is flipped with the chip 210 facing downward. The chip 210 is then aligned with the recess R1 of the first substrate 200. Referring to FIG. 32, the second substrate 202 is bonded to the first substrate 200 using, for example, soldering. As such, the second substrate 202 covers the recess R1 and a portion of the first substrate 200. The chip 210 is disposed inside the recess R1. The chip 210 may be electrically connected to an electrical circuitry of the first substrate 200 via the second substrate 202. A space 205 may be defined by the first substrate 200, the second substrate 202 and the chip 210.

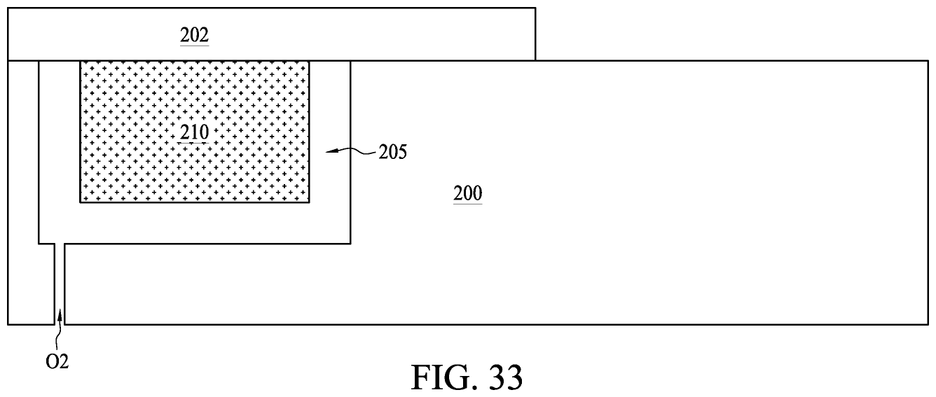

In operation 507, a hole O2 is formed penetrating the first substrate 200, as shown in FIG. 33. In some embodiments, the hole O2 is formed by a laser drilling process.

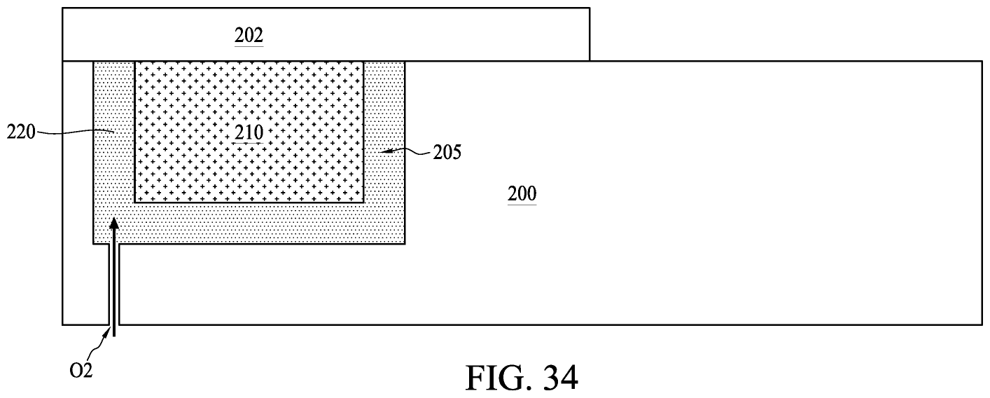

In operation 509, a molding material 220 is injected into the space 205 in the first substrate 200 through the hole O2, as shown in FIG. 34. The molding material 220 may be the same as or similar to the molding material 120. As the molding material 220 fills the space 205, the chip 210 is encapsulated by the molding material 220. The molding material 220 may be in direct contact with the second substrate 202.

After the molding material 220 is injected, the molding material 220 gradually hardens as its solvent evaporates. In some embodiments, a curing operation is performed on the molding material 220. The curing operation may include heating or light illumination of the molding material 220 to cause the molding material 220 to be sufficiently solidified.

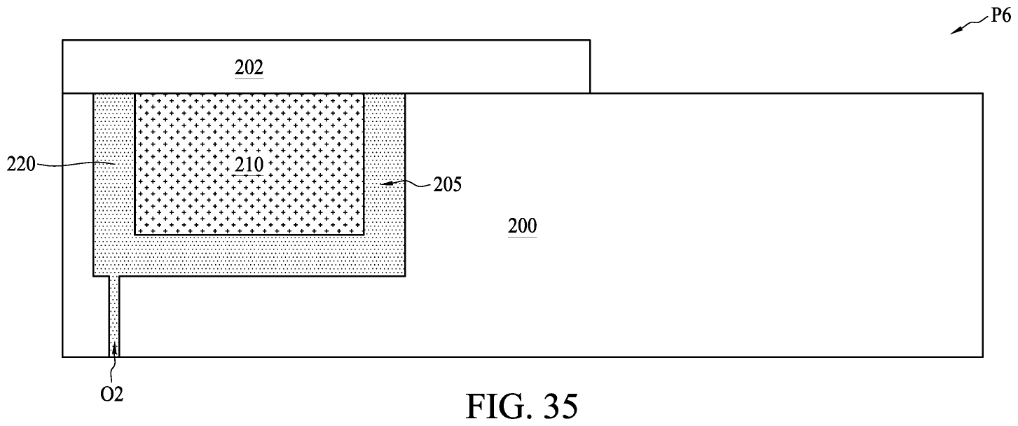

In operation 511, the hole O2 is sealed by the molding material 220, as shown in FIG. 35. After the molding material 220 in the space 205 becomes solidified, more molding material 220 may be injected to fill the hole O2. At this stage, the semiconductor package structure P6 shown in FIG. 7 is formed.

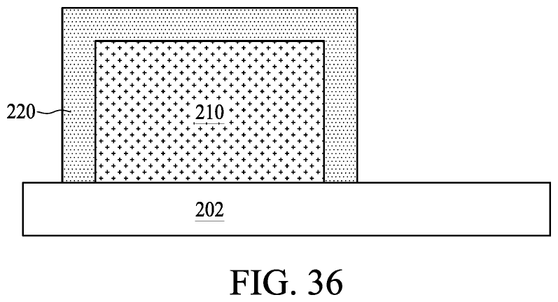

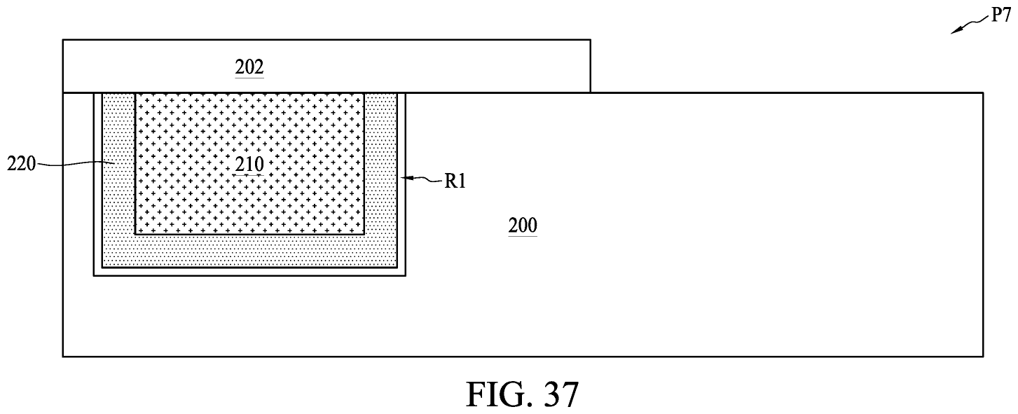

Referring to FIGS. 36 and 37, in some other embodiments, the chip 210 disposed on the second substrate 202 is encapsulated by the molding material 220 before the second substrate 202 is mounted onto the first substrate 200, as shown in FIG. 36. The chip 210 and the second substrate 202 are then flipped with the chip 210 facing downward and aligned with the recess R1 of the first substrate 200. Subsequently, the second substrate 202 is bonded to the first substrate 200 using, for example, soldering. At this stage, the semiconductor package structure P7 shown in FIG. 8 is formed.

The present disclosure provides various semiconductor package structures P1 to P7 and various methods 300, 400 and 500 for manufacturing thereof. Each of the semiconductor package structures P1 to P5 includes a molding material 120 for protecting the chip 110, and each of the semiconductor package structures P6 and P7 includes a molding material 220 for protecting the chip 210. The chips 110 and 210 are MEMS integrated chips which include one or more movable elements 118 and one or more cavities C1 disposed therein. Each of the cavities C1 is aligned with each of the movable elements 118. The movable element 118 may freely oscillate, shift, expand or contact inside the cavity C1 for sensing or outputting a force.

The movable element 118 between the device substrate 112 and the capping member 116 and within the cavity C1 may be sensitive to vibrations. Conventional methods for reducing a shock impact on a movable element inside a semiconductor package structure include disposing some parts or fillers inside the semiconductor package structure. For example, a spring may be disposed between an exterior surface of a chip including the movable element and an interior surface of the semiconductor package structure. In some other examples, cotton, foam or binders may be used to surround or envelop the chip before the chip is packaged. However, these methods still cannot effectively reduce the impact of shock on the chip. In some cases, the use of the above materials still cannot make the semiconductor package structure pass a reliability test. Furthermore, when sizes of the semiconductor package structures decrease, these parts or fillers are not easy to be disposed inside the semiconductor package structure.

The molding material 120 or 220 of the present disclosure is injected into space inside the housing 130, the mold 132 or the first substrate 200 in the form of gel or liquid solution and then solidified. The injection of the molding material 120 or 220 is not limited by sizes of semiconductor package structures. In addition, the amount or composition of the molding material 120 or 220 may be adjusted such that the molding material 120 or 220 can have a sufficient shock absorption capacity. The semiconductor package structures P1 to P7 provided by the present disclosure can pass the reliability test.

One aspect of the present disclosure provides a semiconductor package structure. The semiconductor package structure includes: a substrate; a chip disposed on the substrate; and a molding material disposed on the substrate and surrounding the chip. The chip includes: a cavity; and a movable element disposed within and movable within the cavity and configured to sense or output a force.

One aspect of the present disclosure provides another semiconductor package structure. The semiconductor package structure includes: a first substrate including a recess; a chip disposed within the recess and including a cavity and a movable element, wherein the movable element is disposed within and movable within the cavity; a molding material disposed within the recess and surrounding the chip; and a second substrate covering and contacting the chip, the molding material and at least a portion of the first substrate.

Another aspect of the present disclosure provides a method for manufacturing a semiconductor package structure. The method includes: disposing a chip on a substrate, wherein the chip includes a cavity and a movable element disposed within and movable within the cavity; placing a housing on the substrate to cover the chip; and injecting a molding material into a space defined by the substrate, the chip and the housing, wherein the chip is at least partially surrounded by the molding material.

The foregoing outlines features of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods and steps.

1. A semiconductor package structure, comprising:
a substrate;
a chip disposed on the substrate; and
a molding material disposed on the substrate and surrounding the chip,
wherein the chip includes:
a cavity; and
a movable element disposed within and movable within the cavity and configured to sense or output a force.

2. The semiconductor package structure of claim 1, wherein the chip is a MEMS device.

3. The semiconductor package structure of claim 1, wherein a top surface of the molding material is substantially coplanar with a top surface of the chip exposed through the molding material.

4. The semiconductor package structure of claim 1, wherein the molding material covers the chip and the substrate.

5. The semiconductor package structure of claim 1, further comprising a housing disposed on the substrate, covering the chip and the molding material.

6. The semiconductor package structure of claim 5, wherein a top surface of the molding material is between a top surface of the chip and an interior surface of the housing facing the top surface of the chip.

7. The semiconductor package structure of claim 5, wherein a space defined by the substrate, the housing and the chip is completely filled by the molding material.

8. The semiconductor package structure of claim 5, wherein an exterior surface of the housing is coupled to and coplanar with a sidewall of the substrate.

9. The semiconductor package structure of claim 5, wherein the housing is made of a metallic material.

10. A semiconductor structure, comprising:
a first substrate including a recess;
a chip disposed within the recess and including a cavity and a movable element, wherein the movable element is disposed within and movable within the cavity;
a molding material disposed within the recess and surrounding the chip; and
a second substrate covering and contacting the chip, the molding material and at least a portion of the first substrate.

11. The semiconductor structure of claim 10, wherein a sidewall of the recess is entirely covered by the molding material.

12. The semiconductor structure of claim 10, wherein the molding material is spaced apart from the first substrate.

13. The semiconductor structure of claim 10, wherein the molding material and the chip completely fill the recess of the first substrate.

14. A method for manufacturing a semiconductor package structure, comprising:
disposing a chip on a substrate, wherein the chip includes a cavity and a movable element disposed within and movable within the cavity;
placing a housing on the substrate to cover the chip; and
injecting a molding material into a space defined by the substrate, the chip and the housing, wherein the chip is at least partially surrounded by the molding material.

15. The method of claim 14, wherein the molding material is injected into the space until a top surface of the chip is entirely covered by the molding material.

16. The method of claim 14, further comprising solidifying the molding material by heating or light illumination after the injecting the molding material into the space.

17. The method of claim 14, further comprising:
forming a hole through the housing prior to the injecting of the molding material into the space; and
sealing the hole after the injecting of the molding material into the space.

18. The method of claim 17, wherein the molding material fills the space and seals the hole.

19. The method of claim 14, further comprising removing the housing after the injecting of the molding material into the space.

20. The method of claim 19, wherein after the housing is removed, an edge of the substrate protrudes from the molding material.
